(19) United States
(12) Patent Application Publication
(10) Pub. No.: US 2012/0174944 A1
(43) Pub. Date: Jul. 12, 2012

(54) CLEANING METHOD FOR SILICON CARBIDE SEMICONDUCTOR AND CLEANING APPARATUS FOR SILICON CARBIDE SEMICONDUCTOR

(75) Inventors: Tomihito Miyazaki, Osaka-shi (JP); Keiji Wada, Osaka-shi (JP); Toru Hiyoshi, Osaka-shi (JP)

(73) Assignee: Sumitomo Electric Industries, Ltd., Osaki-shi (JP)

(21) Appl. No.: 13/496,754

(22) PCT Filed: Apr. 21, 2011
(86) PCT No.: PCT/JP2011/059822

§ 371 Date: Mar. 16, 2012

(30) Foreign Application Priority Data
Jun. 16, 2010 (JP) 2010-136868

(51) Int. Cl. H01L 21/30; B08B 7/04; B08B 5/00

(52) U.S. Cl. 134/1.2; 134/133; 257/E21.224

(57) ABSTRACT

A cleaning method for a SiC semiconductor includes the step of forming an oxide film on a front surface of a SiC semiconductor, and the step of removing the oxide film, and oxygen plasma is used in the step of forming the oxide film. Hydrogen fluoride may be used in the step of removing the oxide film. Thereby, a cleaning effect on the SiC semiconductor can be exhibited.

### TECHNICAL FIELD

The present invention relates to a cleaning method for a silicon carbide (SiC) semiconductor and a cleaning apparatus for a SiC semiconductor. More particularly, the present invention relates to a cleaning method for a SiC semiconductor used for a semiconductor device having an oxide film, and a cleaning apparatus for the SiC semiconductor.

### BACKGROUND ART

Conventionally, in methods of manufacturing semiconductor devices, cleaning is performed to remove matter adhering to a front surface. Examples of such a cleaning method include techniques disclosed in Japanese Patent Laying-Open Nos. 6-314679 (Patent Literature 1) and 4-354334 (Patent Literature 2).

A cleaning method for a semiconductor substrate disclosed in Patent Literature 1 is performed as described below. Firstly, a silicon (Si) substrate is cleaned with ultrapure water containing ozone to form a Si oxide film, and particles and metal impurities are taken in into an inside and a front surface of the Si oxide film. Next, the Si substrate is cleaned with a dilute hydrofluoric acid aqueous solution to remove the Si oxide film by etching and simultaneously remove the particles and metal impurities.

In a cleaning method for a semiconductor disclosed in Patent Literature 2, pure water containing 1 to 5 ppm of ozone is sprayed onto the semiconductor to remove foreign components adhering to a front surface by the oxidation action of ozone.

Further, examples of a technique using ozone in a process of manufacturing a semiconductor device include a technique disclosed in Japanese Patent Laying-Open No. 2002-33300 (Patent Literature 3). Patent Literature 3 discloses a technique of supplying pure water containing ozone to an ozone water contact apparatus under conditions including a temperature of not less than about 22° C. and a dissolved ozone concentration of not less than about 30 ppm, bringing the pure water containing ozone into contact with a substrate having a photoresist film remaining thereon, and removing the photoresist film.

### CITATION LIST

### Patent Literature

PTL 1: Japanese Patent Laying-Open No. 6-314679

PTL 2: Japanese Patent Laying-Open No. 4-354334

PTL 3: Japanese Patent Laying-Open No. 2002-33300

### SUMMARY OF INVENTION

### Technical Problem

SiC has a large bandgap, the maximum breakdown electric field and heat conductivity larger than those of Si, carrier mobility as large as that of Si, a large saturated drift velocity of electrons, and a large breakdown voltage. Accordingly, it is expected to be applied to semiconductor devices which are required to have higher efficiency, higher breakdown voltage, and higher capacity. Thus, the inventors of the present invention focused attention on using a SiC semiconductor for a semiconductor device. Therefore, if a SiC semiconductor is used for a semiconductor device, it is necessary to clean a front surface of the SiC semiconductor.

However, if the cleaning methods described in Patent Literatures 1 and 2 are applied to a SiC semiconductor, a front surface of the SiC semiconductor is less likely to be oxidized, because SiC is a compound that is thermally more stable than Si. Specifically, although the cleaning methods described in Patent Literatures 1 and 2 can oxidize a front surface of Si, they cannot fully oxidize a front surface of SiC. Therefore, they cannot fully clean the front surface of SiC.

In addition, although the method of removing the photoresist film in Patent Literature 3 discloses conditions for removing the photoresist film, it does not disclose a method for removing impurities and particles adhering to a semiconductor front surface. Further, when a front surface of a Si substrate is cleaned with the pure water containing ozone disclosed in the method of removing the photoresist film in Patent Literature 3, the front surface of the Si substrate becomes roughened due to too strong oxidation power of the pure water containing ozone. That is, the method of removing the photoresist film in Patent Literature 3 is a technique intended to remove the photoresist film, and does not disclose a cleaning method for removing impurities and particles existing on a front surface of a semiconductor made of Si, SiC, or the like.

Consequently, one object of the present invention is to provide a cleaning method for a SiC semiconductor and a cleaning apparatus for a SiC semiconductor capable of exhibiting a cleaning effect on the SiC semiconductor.

### Solution to Problem

A cleaning method for a SiC semiconductor in accordance with the present invention includes the steps of forming an oxide film on a front surface of a SiC semiconductor, and removing the oxide film, wherein oxygen (O) plasma is used in the step of forming the oxide film.

According to the cleaning method for a SiC semiconductor in accordance with the present invention, the oxide film can be easily formed on the front surface of the SiC semiconductor, which is a strongly-coupled and stable compound, by using O plasma. Thus, impurities, particles, and the like adhering to the front surface can be easily taken in into the oxide film. By removing the oxide film, impurities, particles, and the like on the front surface of the SiC semiconductor can be removed. Further, since the SiC semiconductor is a stable compound, the SiC semiconductor is less damaged even if O plasma is used. Therefore, the cleaning method for a SiC semiconductor in accordance with the present invention can exhibit a cleaning effect on the SiC semiconductor.

Preferably, in the cleaning method for a SiC semiconductor described above, in the step of forming the oxide film, the oxide film is formed at a temperature of not less than 200° C. and not more than 700° C.

Thereby, the oxide film can be formed with improved throughput. Further, since electric power can be reduced, the oxide film can also be formed with reduced cost. Furthermore, the oxide film to be formed can also have improved uniformity.

Preferably, in the cleaning method for a SiC semiconductor described above, in the step of forming the oxide film, the oxide film is formed at a pressure of not less than 0.1 Pa and not more than 20 Pa.

In this case, reactivity of O plasma with the front surface of the SiC semiconductor can be enhanced, and thus the oxide film can be formed more easily.

Preferably, in the cleaning method for a SiC semiconductor described above, hydrogen fluoride (HF) is used in the step of removing the oxide film.

Thereby, the oxide film can be easily removed, and thus the oxide film remaining on the front surface can be reduced.

Preferably, in the cleaning method for a SiC semiconductor described above, the SiC semiconductor is disposed in an atmosphere cut off from air between the step of forming the oxide film and the step of removing the oxide film.

This can suppress impurities in the air from adhering again to the front surface of the SiC semiconductor. Therefore, the cleaning effect on the SiC semiconductor can be further enhanced.

A cleaning apparatus for a SiC semiconductor in accordance with one aspect of the present invention includes a formation unit, a removal unit, and a connection unit. The formation unit forms an oxide film on a front surface of a SiC semiconductor using O plasma. The removal unit removes the oxide film. The connection unit connects the formation unit and the removal unit to allow the SiC semiconductor to be transported. A region for transporting the SiC semiconductor in the connection unit can be cut off from air.

A cleaning apparatus for a SiC semiconductor in accordance with another aspect of the present invention includes a formation unit for forming an oxide film on a front surface of a SiC semiconductor using O plasma, and a removal unit for removing the oxide film, wherein the formation unit and the removal unit are identical.

According to the cleaning apparatus for a SiC semiconductor in accordance with one and another aspects of the present invention, the oxide film can be easily formed on the front surface of the SiC semiconductor, which is a stable compound, by the formation unit using O plasma. Thereby, impurities, particles, and the like adhering to the front surface of the SiC semiconductor can be easily taken in into the oxide film. By removing the oxide film in the removal unit, impurities, particles, and the like on the front surface of the SiC semiconductor can be removed.

Further, the SiC semiconductor can be suppressed from being exposed to the air after the oxide film is formed on the SiC semiconductor in the formation unit and while the oxide film is removed in the removal unit. This can suppress impurities in the air from adhering again to the front surface of the SiC semiconductor.

Therefore, the cleaning apparatus for a SiC semiconductor in accordance with one and another aspects of the present invention can exhibit a cleaning effect on the SiC semiconductor.

### Advantageous Effects of Invention

As described above, according to the cleaning method and the cleaning apparatus for a SiC semiconductor in accordance with the present invention, a cleaning effect on the SiC semiconductor can be exhibited by forming an oxide film on the front surface of the SiC semiconductor using O plasma.

### BRIEF DESCRIPTION OF DRAWINGS

FIG. 1 is a schematic view of a cleaning apparatus for a SiC semiconductor in accordance with Embodiment 1 of the present invention.

FIG. 2 is a cross sectional view schematically showing the SiC semiconductor prepared in accordance with Embodiment 1 of the present invention.

FIG. 3 is a flowchart illustrating a cleaning method for the SiC semiconductor in accordance with Embodiment 1 of the present invention.

FIG. 4 is a cross sectional view schematically showing a state where an oxide film is formed on the SiC semiconductor in accordance with Embodiment 1 of the present invention.

FIG. 5 is a cross sectional view schematically showing a state where the oxide film is removed in accordance with Embodiment 1 of the present invention.

FIG. 6 is a schematic view of a cleaning apparatus for a SiC semiconductor in accordance with a modification of Embodiment 1 of the present invention.

FIG. 7 is a cross sectional view schematically showing a SiC semiconductor to be cleaned in accordance with Embodiment 2 of the present invention.

FIG. 8 is a flowchart illustrating a cleaning method for the SiC semiconductor in accordance with Embodiment 2 of the present invention.

FIG. 9 is a cross sectional view schematically showing one step of the cleaning method for the SiC semiconductor in accordance with Embodiment 2 of the present invention.

FIG. 10 is a cross sectional view schematically showing one step of the cleaning method for the SiC semiconductor in accordance with Embodiment 2 of the present invention.

FIG. 11 is a cross sectional view schematically showing one step of the cleaning method for the SiC semiconductor in accordance with Embodiment 2 of the present invention.

FIG. 12 is a cross sectional view schematically showing an epitaxial wafer to be cleaned in Examples.

### DESCRIPTION OF EMBODIMENTS

Hereinafter, embodiments of the present invention will be described with reference to the drawings, in which identical or corresponding parts will be designated by the same reference numerals, and the description thereof will not be repeated.

### Embodiment 1

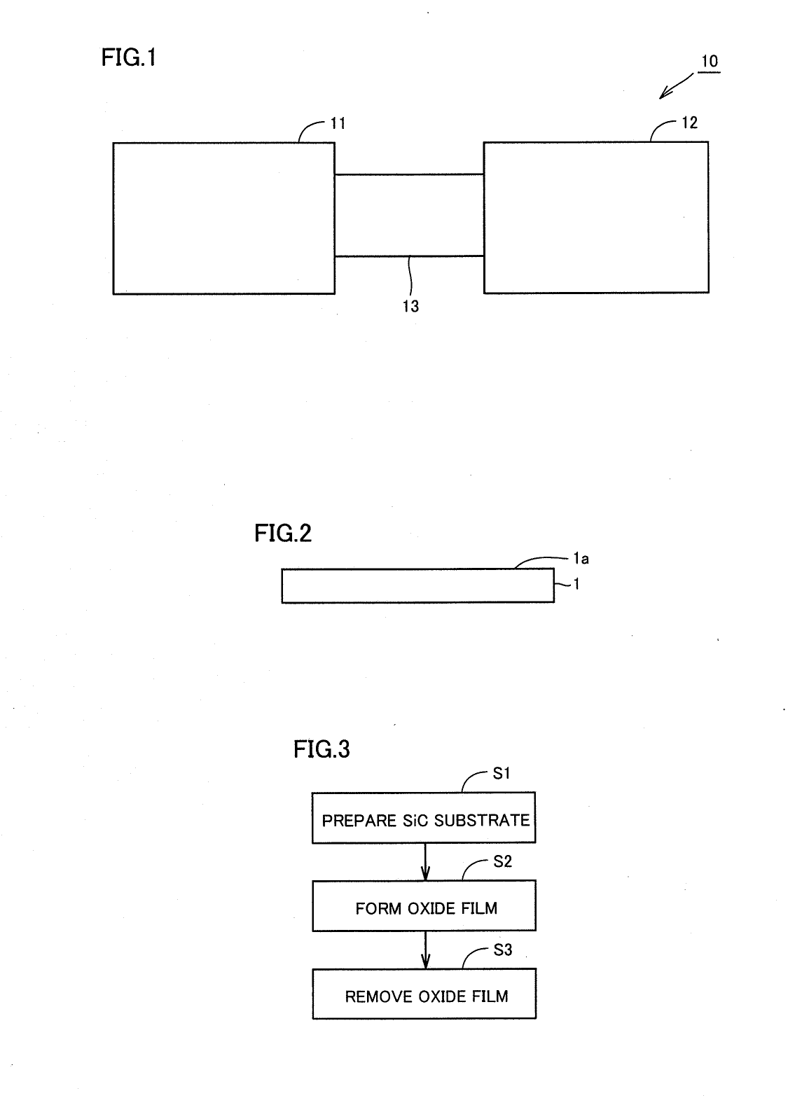

FIG. 1 is a schematic view of a cleaning apparatus 10 for a SiC semiconductor in accordance with Embodiment 1 of the present invention. Referring to FIG. 1, cleaning apparatus 10 for a SiC semiconductor in accordance with one embodiment of the present invention will be described.

As shown in FIG. 1, cleaning apparatus 10 for a SiC semiconductor includes a formation unit 11, a removal unit 12, and a connection unit 13. Formation unit 11 and removal unit 12 are connected by connection unit 13. Insides of formation unit 11, removal unit 12, and connection unit 13 are cut off from air, and the insides can communicate with each other.

Formation unit 11 forms an oxide film on a front surface of a SiC semiconductor. Formation unit 11 forms the oxide film using O plasma. As formation unit 11, a plasma generator or the like is used.

Removal unit 12 removes the oxide film formed by formation unit 11. As removal unit 12, for example, a plasma generator, an apparatus for removing an oxide film using a solution capable of reducing an oxide film such as HF, a thermal decomposition apparatus, or the like is used. Preferably, removal unit 12 removes the oxide film using halogen plasma or H plasma.

The plasma generator used as formation unit 11 and removal unit 12 is not particularly limited, and, for example, a parallel plate type Reactive Ion Etching (RIE) apparatus, an Inductive Coupled Plasma (ICP) type RIE apparatus, an Electron Cyclotron Resonance (ECR) type RIE apparatus, a Surface Wave Plasma (SWP) type RIE apparatus, a Chemical Vapor Deposition (CVD) apparatus, or the like is used.

Connection unit 13 connects formation unit 11 and removal unit 12 to allow a SiC substrate 1 to be transported. A region (i.e., an inner space) for transporting SiC substrate 1 in connection unit 13 can be cut off from the air.

Here, cutting off from the air (i.e., an atmosphere cut off from the air) refers to an atmosphere into which no air is introduced, for example, a vacuum atmosphere, or an atmosphere containing an inert gas or nitrogen gas. Specifically, the atmosphere cut off from the air is, for example, a vacuum atmosphere, or an atmosphere filled with a gas such as nitrogen (N), helium (He), neon (Ne), argon (Ar), krypton (Kr), xenon (Xe), radon (Rn), or a combination thereof.

In the present embodiment, connection unit 13 couples the inside of formation unit 11 and the inside of removal unit 12. Connection unit 13 has a space for transporting the SiC semiconductor discharged from formation unit 11 to removal unit 12, in the inside thereof. Specifically, connection unit 13 is installed to transport the SiC semiconductor from formation unit 11 to removal unit 12 without exposing the SiC semiconductor to the air.

Connection unit 13 has a size which allows SiC substrate 1 to be transported therein. Further, connection unit 13 may have a size which allows SiC substrate 1 placed on a susceptor to be transported. Connection unit 13 is, for example, a load lock chamber coupling an exit of formation unit 11 and an entrance of removal unit 12.

Further, cleaning apparatus 10 may further include a first transport unit disposed inside connection unit 13 for transporting the SiC semiconductor from formation unit 11 to removal unit 12. Cleaning apparatus 10 may further include a second transport unit for taking the SiC semiconductor from which the oxide film has been removed by removal unit 12, out of cleaning apparatus 10, or transporting the SiC semiconductor to an oxide film formation unit for forming an oxide film constituting a semiconductor device, in an atmosphere cut off from the air. The first transport unit and the second transport unit may be identical or different.

Furthermore, cleaning apparatus 10 may further include a first cut-off unit disposed between formation unit 11 and connection unit 13 for cutting off the inside of formation unit 11 from the inside of connection unit 13. Cleaning apparatus 10 may further include a second cut-off unit disposed between removal unit 12 and connection unit 13 for cutting off the inside of removal unit 12 from the inside of connection unit 13. As the cut-off units, for example, a valve, a door, or the like that can close each communicating portion can be used.

In addition, cleaning apparatus 10 may further include a vacuum pump for exhausting an inside atmosphere gas, and a replacement gas cylinder for replacing an inside atmosphere gas. The vacuum pump and the replacement gas cylinder may be connected to each of formation unit 11, removal unit 12, and connection unit 13, or may be connected to at least one of them.

Although cleaning apparatus 10 may include various elements other than those described above, diagrammatic representation and description of these elements will be omitted for convenience of description.

Further, although FIG. 1 shows connection unit 13 having a shape coupling only formation unit 11 and removal unit 12, the present invention is not particularly limited thereto. For example, a chamber cut off from the air may be used as connection unit 13, and formation unit 11 and removal unit 12 may be disposed within the chamber.

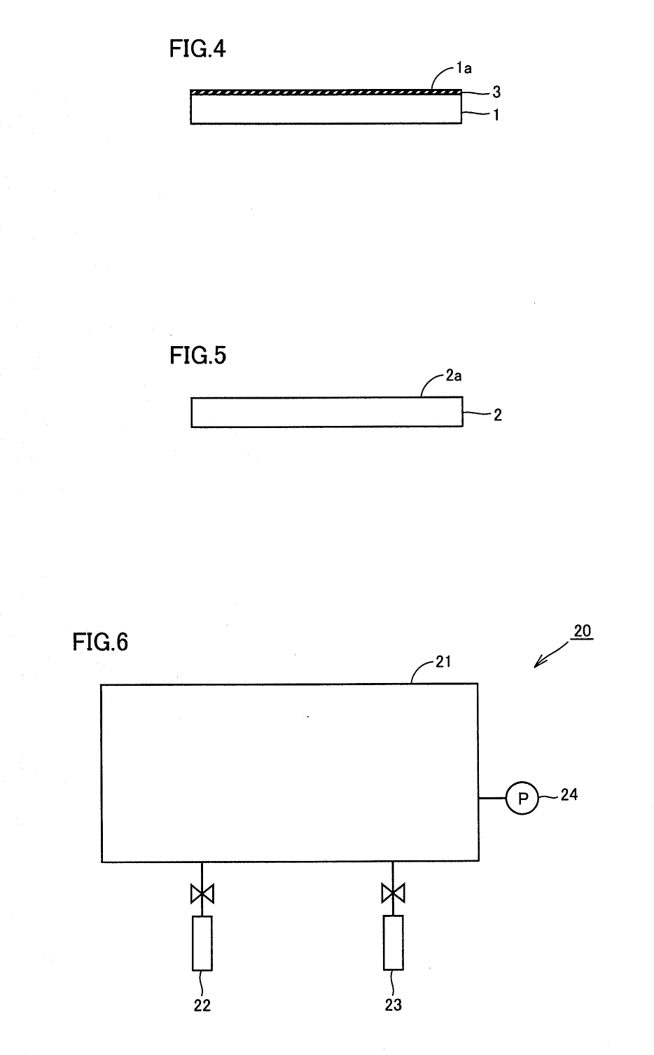

FIG. 2 is a cross sectional view schematically showing the SiC semiconductor prepared in accordance with Embodiment 1 of the present invention. FIG. 3 is a flowchart illustrating a cleaning method for the SiC semiconductor in accordance with Embodiment 1 of the present invention. FIG. 4 is a cross sectional view schematically showing a state where an oxide film is formed on the SiC semiconductor in accordance with Embodiment 1 of the present invention. FIG. 5 is a cross sectional view schematically showing a state where the oxide film is removed in accordance with Embodiment 1 of the present invention. Next, referring to FIGS. 1 to 5, a cleaning method for the SiC semiconductor in accordance with one embodiment of the present invention will be described. In the present embodiment, a method of cleaning SiC substrate 1 shown in FIG. 2 as the SiC semiconductor will be described. Further, in the present embodiment, cleaning apparatus 10 for the SiC semiconductor shown in FIG. 1 will be used.

Firstly, as shown in FIGS. 2 and 3, SiC substrate 1 having a front surface 1a is prepared (step S1). Although SiC substrate 1 is not particularly limited, it can be prepared, for example, by a method described below.

Specifically, a SiC ingot grown for example by a vapor phase growth method such as a Hydride Vapor Phase Epitaxy (HVPE) method, a Molecular Beam Epitaxy (MBE) method, an OrganoMetallic Vapor Phase Epitaxy (OMVPE) method, a sublimation method, and a CVD method; a liquid phase growth method such as a flux method and a high nitrogen pressure solution method; or the like is prepared.

Thereafter, a SiC substrate having a front surface is cut out from the SiC ingot. A method of cutting out the SiC substrate is not particularly limited, and the SiC substrate is cut out from the SiC ingot by slicing or the like. Subsequently, the front surface of the cut-out SiC substrate is polished. Only the front surface may be polished, or a back surface opposite to the front surface may further be polished. Although a polishing method is not particularly limited, for example, Chemical Mechanical Polishing (CMP) is employed to planarize the front surface and reduce damage such as flaws. In CMP, colloidal silica is used as a polishing agent, diamond or chromic oxide is used as abrasive grains, and an adhesive, wax, or the like is used as a fixing agent. In addition to or instead of CMP, other polishing such as an electric field polishing method, a chemical polishing method, and a mechanical polishing method may further be performed. Further, polishing may be omitted. Thereby, SiC substrate 1 having front surface 1a shown in FIG. 2 can be prepared. As such SiC substrate 1, for example, a substrate having n conductivity type and a resistance of 0.02 Ωcm is used.

Next, as shown in FIGS. 3 and 4, an oxide film 3 is formed on front surface 1a of SiC substrate 1 (step S2). In step S2, oxide film 3 is formed using O plasma. In step S2 of the present embodiment, oxide film 3 is formed by formation unit 11 of cleaning apparatus 10 shown in FIG. 1.

Here, O plasma means plasma generated from a gas containing O element, and can be generated, for example, by supplying O gas to a plasma generator. “To form oxide film 3 using O plasma” means to form oxide film 3 using plasma that uses a gas containing O element. In other words, it means to form oxide film 3 by being treated with plasma generated from a gas containing O element.

In step S2, oxide film 3 is preferably formed at not less than 200° C. and not more than 700° C. Forming oxide film 3 at not less than 200° C. and not more than 700° C. can be implemented, for example, by heating the back surface opposite to front surface 1a of SiC substrate 1 at not less than 200° C. and not more than 700° C. If oxide film 3 is formed at not less than 200° C. and not more than 700° C., oxide film 3 can be formed with improved throughput. Further, since electric power can be reduced, oxide film 3 can be formed with reduced cost. Furthermore, oxide film 3 can be formed uniformly.

In addition, in step S2, oxide film 3 is formed in an atmosphere of not less than 0.1 Pa and not more than 20 Pa. In this case, reactivity with front surface 1a of SiC substrate 1 can be enhanced.

In step S2, oxide film 3 having a thickness of, for example, not less than one molecular layer and not more than 30 nm is formed. By forming oxide film 3 having a thickness of not less than one molecular layer, oxide film 3 can take in impurities, particles, and the like on front surface 1a. By forming oxide film 3 having a thickness of not more than 30 nm, oxide film 3 can be easily removed in step S3 described later.

By performing step S2, particles, metal impurities, and the like adhering to front surface 1a of SiC substrate 1 can be taken in into a front surface and an inside of oxide film 3. It is to be noted that oxide film 3 is, for example, silicon oxide.

Next, referring to FIG. 1, SiC substrate 1 having oxide film 3 formed by formation unit 11 is transported to removal unit 12. On this occasion, SiC substrate 1 is transported within connection unit 13 having the atmosphere cut off from the air. In other words, SiC substrate 1 is disposed in the atmosphere cut off from the air between step S2 of forming oxide film 3 and step S3 of removing oxide film 3. This can suppress impurities contained in the air from adhering to SiC substrate 1 after oxide film 3 is formed.

Subsequently, as shown in FIGS. 3 and 5, oxide film 3 is removed (step S3). In step S3 of the present embodiment, oxide film 3 is removed by removal unit 12 of cleaning apparatus 10 shown in FIG. 1.

A method of removing oxide film 3 is not particularly limited, and, for example, halogen plasma, H plasma, thermal decomposition, dry etching, wet etching, or the like can be used.

Halogen plasma means plasma generated from a gas containing a halogen element. Halogen elements include fluorine (F), chlorine (Cl), bromine (Br), and iodine (I). “To remove oxide film 3 using halogen plasma” means to etch oxide film 3 using plasma that uses a gas containing a halogen element. In other words, “to remove oxide film 3 using halogen plasma” means to remove oxide film 3 by treatment using plasma generated from a gas containing a halogen element.

Preferably, F plasma is used as halogen plasma. F plasma means plasma generated from a gas containing F element, and can be generated, for example, by supplying to a plasma generator a single gas such as carbon tetrafluoride (CF₄), methane trifluoride (CHF₃), chlorofluorocarbon (C₂F₆), sulfur hexafluoride (SF₆), nitrogen trifluoride (NF₃), xenon difluoride (XeF₂), fluorine (F₂), and chlorine trifluoride (ClF₃), or a mixed gas thereof. “To remove oxide film 3 using F plasma” means to remove oxide film 3 using plasma that uses a gas containing F element. In other words, “to remove oxide film 3 using F plasma” means to remove oxide film 3 by treatment using plasma generated from a gas containing F element.

H plasma means plasma generated from a gas containing H element, and can be generated, for example, by supplying H₂ gas to a plasma generator. “To remove oxide film 3 using H plasma” means to etch oxide film 3 using plasma that uses a gas containing H element. In other words, “to remove oxide film 3 using H plasma” means to remove oxide film 3 by being treated with plasma generated from a gas containing H element.

If halogen plasma or H plasma is used in step S3, it is preferable to remove oxide film 3 at a temperature of not less than 20° C. and not more than 400° C. In this case, damage to SiC substrate 1 can be reduced.

Further, if halogen plasma or H plasma is used in step S3, it is preferable to remove oxide film 3 at a pressure of not less than 0.1 Pa and not more than 20 Pa. In this case, reactivity of halogen plasma or H plasma with oxide film 3 can be enhanced, and thus oxide film 3 can be easily removed.

Regarding thermal decomposition, it is preferable to thermally decompose oxide film 3 in an atmosphere not containing O, at not less than 1200° C. and not more than the sublimation temperature of SiC. If oxide film 3 is heated in the atmosphere not containing O at not less than 1200° C., oxide film 3 can be easily thermally decomposed. Setting the temperature to not more than the sublimation temperature of SiC can suppress deterioration of SiC substrate 1. Further, thermal decomposition is preferably performed under reduced pressure, from the viewpoint of the ability to promote reaction.

Regarding dry etching, oxide film 3 is removed, for example, at not less than 1000° C. and not more than the sublimation temperature of SiC, using at least one of hydrogen (H₂) gas and hydrogen chloride (HCl) gas. Hydrogen gas and hydrogen chloride gas at not less than 1000° C. are highly effective in reducing oxide film 3. If the oxide film is SiOₓ, hydrogen gas decomposes SiOₓ into H₂O and SiH_{y}, and hydrogen chloride gas decomposes SiOₓ into H₂O and SiCl_{z}. Setting the temperature to not more than the sublimation temperature of SiC can suppress deterioration of an epitaxial wafer 100. Further, dry etching is preferably performed under reduced pressure, from the viewpoint of the ability to promote reaction.

Regarding wet etching, oxide film 3 is removed, for example, using a solution of such as HF or NH₄F (ammonium fluoride). For wet etching, it is preferable to use HF, and it is more preferable to use dilute HF (DHF) with a concentration of not less than 1% and not more than 10%. If oxide film 3 is removed using HF, oxide film 3 can be removed, for example, by storing HF in a reaction container and immersing SiC substrate 1 in HF.

If wet cleaning using a liquid phase such as wet etching is performed, front surface 1a of SiC substrate 1 may be cleaned with pure water (i.e., a pure water rinsing step) after wet cleaning. Pure water is preferably ultrapure water. Cleaning may be performed by applying ultrasonic waves to pure water. The pure water rinsing step may be omitted.

Further, if wet cleaning is performed, front surface 1a of SiC substrate 1 may be dried (i.e., a drying step). Although a drying method is not particularly limited, front surface 1a is dried, for example, by a spin dryer or the like. The drying step may be omitted.

By performing step S3, oxide film 3 which has taken in impurities, particles, and the like in step S2 can be removed. Thus, impurities, particles, and the like adhering to front surface 1a of SiC substrate 1 prepared in step S1 can be removed.

By performing the above steps (steps S1 to S3), a SiC substrate 2 having a front surface 2a with reduced impurities and particles as shown for example in FIG. 5 can be implemented.

The above steps S2 and S3 may be repeated. Further, a cleaning step using another solution, the pure water rinsing step, the drying step, or the like may be additionally performed after step S1, as necessary. Examples of another solution include SPM containing sulfuric acid and hydrogen peroxide water. If cleaning using SPM is performed before step S2, organic matter can also be removed. Further, RCA cleaning or the like may be performed before step S2.

As described above, a cleaning method for SiC substrate 1 as a SiC semiconductor in accordance with the present embodiment includes the steps of forming oxide film 3 on front surface 1a of SiC substrate 1 (step S2) and removing oxide film 3 (step S3), and O plasma is used in the step of forming oxide film 3 (step S2).

The inventors of the present invention focused attention on the fact that, when the cleaning method described in Patent Literature 1 is applied to a SiC semiconductor, a front surface of the SiC semiconductor is less likely to be oxidized, because SiC is a compound that is thermally more stable than Si. Specifically, although the cleaning method described in Patent Literature 1 can oxidize a front surface of Si, it cannot fully oxidize a front surface of SiC, and thus it cannot fully clean the front surface of the SiC semiconductor. Thus, the inventors of the present invention earnestly conducted a study to oxidize the front surface of the SiC semiconductor, and as a result found that oxide film 3 can be easily formed by using O plasma and thus utilizing active O. Further, since SiC is crystallographically robust, SiC substrate 1 is less likely to be damaged even if O plasma, which causes damage to a Si substrate, is used. Thus, metal impurities such as titanium (Ti), particles, and the like adhering to front surface 1a can be easily taken in into oxide film 3 in step S2. By removing oxide film 3 in step S3, impurities, particles, and the like on front surface 1a of SiC substrate 1 can be removed. Therefore, the cleaning method for SiC substrate 1 in accordance with the present embodiment can exhibit a cleaning effect on the SiC semiconductor.

Further, in step S2, oxide film 3 is formed using O plasma in a dry atmosphere. Since plasma is clean, it is also environmentally friendly. Further, since post treatment such as washing with water and drying can be omitted in the step of forming oxide film 3 using plasma when compared with a case of forming an oxide film in a wet atmosphere (i.e., an atmosphere including a liquid phase), SiC substrate 1 can be easily cleaned. Furthermore, since there is no need for post treatment such as washing with water, generation of watermarks on front surface 2a of SiC substrate 2 after step S3 can be suppressed.

Preferably, in the cleaning method for SiC substrate 1 as the SiC semiconductor in accordance with the present embodiment, halogen plasma or H plasma is used in the step of removing oxide film 3 (step S3).

By removing oxide film 3 utilizing an active halogen caused by halogen plasma or active H caused by H plasma, influence of anisotropy due to plane orientation of SiC can be reduced. Thus, oxide film 3 formed on front surface 1a of SiC substrate 1 can be removed to reduce in-plane variations. That is, oxide film 3 can be removed uniformly without being influenced by the quality of oxide film 3. Therefore, impurities, particles, and the like on front surface 1a of SiC substrate 1 can be removed to reduce in-plane variations in front surface 1a. Further, oxide film 3 formed on front surface 1a of SiC substrate 1 can also be suppressed from remaining locally. Furthermore, since progress of etching only in a portion of a region in a plane of SiC substrate 1 can be suppressed, local depression in front surface 1a of SiC substrate 1 can also be suppressed. Consequently, SiC substrate 1 can be cleaned to have good front surface characteristics.

Preferably, in the cleaning method for SiC substrate 1 as the SiC semiconductor in accordance with the present embodiment, oxide film 3 is formed on front surface 1a of SiC substrate 1 using O plasma (step S2), and oxide film 3 is removed using halogen plasma or H plasma (step S3). Thereby, front surface 1a of SiC substrate 1 can be cleaned in the dry atmosphere (i.e., in a vapor phase). In cleaning in the wet atmosphere (i.e., the atmosphere including a liquid phase), metal ions may be contained in the liquid phase, instruments, and the like used for cleaning. Further, there is a tendency that particles from a cleaning chamber are likely to be increased. Thus, cleaning in the dry atmosphere can reduce metal impurities and particles on the front surface more than cleaning in the wet atmosphere (i.e., the atmosphere including a liquid phase).

Cleaning apparatus 10 for SiC substrate 1 as the SiC semiconductor in accordance with the present embodiment includes formation unit 11 for forming oxide film 3 on front surface 1a of SiC substrate 1 using O plasma, removal unit 12 for removing oxide film 3, and connection unit 13 for connecting formation unit 11 and removal unit 12 to allow SiC substrate 1 to be transported, and having a region for transporting SiC substrate 1 that can be cut off from the air.

According to cleaning apparatus 10 for SiC substrate 1 in accordance with the present embodiment, oxide film 3 can be easily formed on front surface 1a of SiC substrate 1 as the SiC semiconductor, which is a stable compound, using O plasma. Thereby, impurities, particles, and the like adhering to front surface 1a can be easily taken in into oxide film 3. By removing oxide film 3, impurities, particles, and the like on front surface 1a of SiC substrate 1 can be removed. Therefore, cleaning apparatus 10 for SiC substrate 1 in accordance with the present embodiment can exhibit a cleaning effect on the SiC semiconductor.

In addition, SiC substrate 1 can be suppressed from being exposed to the air after oxide film 3 is formed on SiC substrate 1 in formation unit 11 and while oxide film 3 is removed in removal unit 12. This can suppress impurities in the air from adhering again to front surface 1a of SiC substrate 1. Therefore, SiC substrate 1 can be cleaned to have good front surface characteristics.

(Modification)

FIG. 6 is a schematic view of a cleaning apparatus 20 for a SiC semiconductor in accordance with a modification of Embodiment 1 of the present invention. Cleaning apparatus 20 for a SiC semiconductor in accordance with the modification of the present embodiment will be described with reference to FIG. 6.

As shown in FIG. 6, cleaning apparatus 20 in accordance with the modification includes a chamber 21, a first gas supply unit 22, a second gas supply unit 23, and a vacuum pump 24. The first gas supply unit 22, the second gas supply unit 23, and vacuum pump 24 are connected to chamber 21.

Chamber 21 is a plasma generator which accommodates SiC substrate 1 therein. As the plasma generator, a parallel plate type RIE apparatus, an ICP type RIE apparatus, an ECR type RIB apparatus, a SWP type RIE apparatus, a CVD apparatus, or the like is used.

The first and second gas supply units 22, 23 supply gases from plasma generation sources to chamber 21. The first gas supply unit 22 supplies a gas containing O. Thus, the first gas supply unit 22 can generate O plasma within chamber 21, and thereby oxide film 3 can be formed on front surface 1a of SiC substrate 1. The second gas supply unit 23 supplies a gas containing, for example, halogen or H. Thus, the second gas supply unit 23 can generate halogen plasma or H plasma within chamber 21, and thereby oxide film 3 formed on front surface 1a of SiC substrate 1 can be removed.

Vacuum pump 24 vacuumizes an inside of chamber 21. Thus, after oxide film 3 is formed on front surface 1a of SiC substrate 1 using O plasma, oxide film 3 can be removed using halogen plasma or H plasma with the inside of chamber 21 being vaccumized. It is to be noted that vacuum pump 24 may be omitted.

Although the cleaning apparatus shown in FIG. 6 may include various elements other than those described above, diagrammatic representation and description of these elements will be omitted for convenience of description.

As described above, cleaning apparatus 20 for a SiC semiconductor in accordance with the modification of the present embodiment includes a formation unit for forming oxide film 3 on front surface 1a of SiC substrate 1 as the SiC semiconductor using O plasma, and a removal unit for removing oxide film 3, wherein the formation unit and the removal unit are identical (i.e., chamber 21). That is, in cleaning apparatus 20, the formation unit and the removal unit are used in common.

According to cleaning apparatus 20 for SiC substrate 1 as the SiC semiconductor in accordance with the modification, oxide film 3 can be easily formed on front surface 1a of SiC substrate 1, which is a stable compound, using O plasma. Thereby, impurities, particles, and the like adhering to front surface 1a can be easily taken in into oxide film 3. By removing oxide film 3, impurities, particles, and the like on front surface 1a of SiC substrate 1 can be removed. Therefore, cleaning apparatus 20 for SiC substrate 1 in accordance with the modification can exhibit a cleaning effect on the SiC semiconductor.

In addition, since there is no need to transport SiC substrate 1 after oxide film 3 is formed on SiC substrate 1 in the formation unit and while oxide film 3 is removed in the removal unit, SiC substrate 1 is not exposed to the air. In other words, the SiC substrate is disposed in the atmosphere cut off from the air between step S2 of forming oxide film 3 and step S3 of removing oxide film 3. This can suppress impurities in the air from adhering again to front surface 1a of SiC substrate 1 during cleaning of SiC substrate 1. This can also suppress an increase in contaminants and the like. Therefore, SiC substrate 1 can be cleaned to have good front surface characteristics.

### Embodiment 2

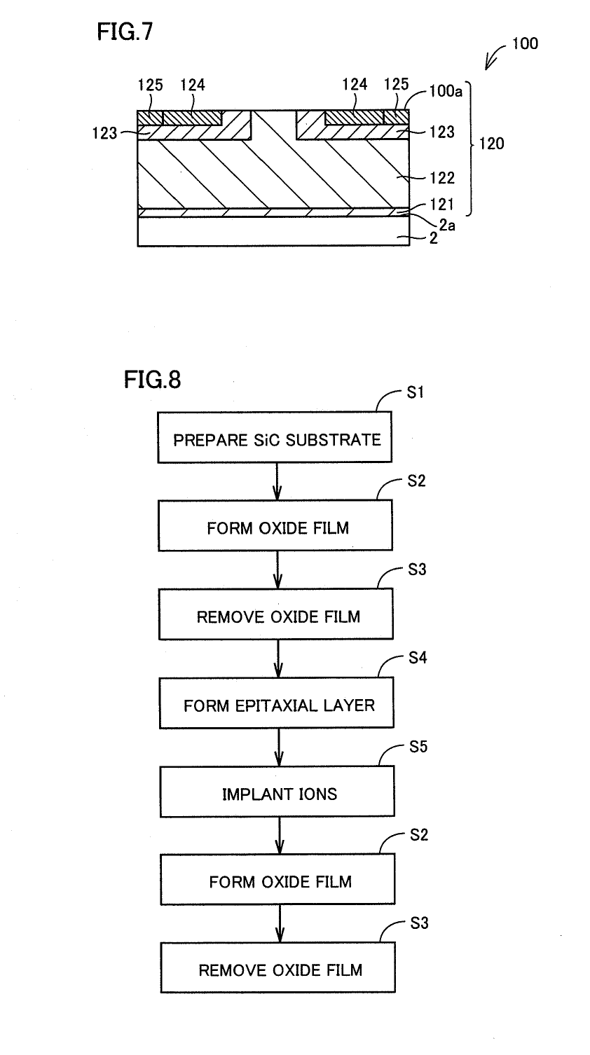

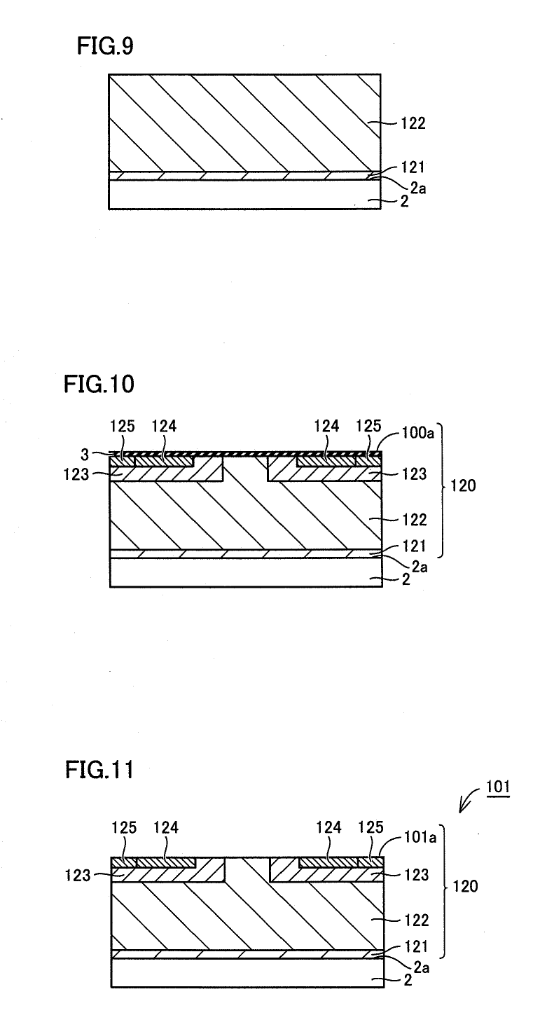

FIG. 7 is a cross sectional view schematically showing a SiC semiconductor to be cleaned in accordance with Embodiment 2 of the present invention. FIG. 8 is a flowchart illustrating a cleaning method for the SiC semiconductor in accordance with Embodiment 2 of the present invention. FIGS. 9 to 11 are cross sectional views each schematically showing one step of the cleaning method for the SiC semiconductor in accordance with Embodiment 2 of the present invention. The cleaning method for the SiC semiconductor in accordance with the present embodiment will be described with reference to FIGS. 2, 4, 5, and 7 to 11. In the present embodiment, a method of cleaning epitaxial wafer 100 including SiC substrate 2 and an epitaxial layer 120 formed on SiC substrate 2 as shown in FIG. 7, as the SiC semiconductor, will be described.

Firstly, SiC substrate 1 is prepared as shown in FIGS. 2 and 8 (step S1). Since step S1 is identical to that in Embodiment 1, the description thereof will not be repeated.

Next, oxide film 3 is formed on front surface 1a of SiC substrate 1 as shown in FIGS. 4 and 8 (step S2), and thereafter oxide film 3 is removed as shown in FIGS. 5 and 8 (step S3). Since steps S2 and S3 are identical to those in Embodiment 1, the description thereof will not be repeated. Thereby, front surface 1a of SiC substrate 1 can be cleaned, and SiC substrate 2 having front surface 2a with reduced impurities and particles can be prepared. It is to be noted that cleaning of front surface 1a of SiC substrate 1 may be omitted.

Next, as shown in FIGS. 7 to 9, epitaxial layer 120 is formed on front surface 2a of SiC substrate 2 by a vapor phase growth method, a liquid phase growth method, or the like (step S4). In the present embodiment, epitaxial layer 120 is formed, for example, as described below.

Specifically, a buffer layer 121 is formed on front surface 2a of SiC substrate 2 as shown in FIG. 9. Buffer layer 121 is an epitaxial layer that is made of, for example, SiC with n conductivity type, and has a thickness of, for example, 0.5 μm. Further, conductive impurities in buffer layer 121 have a concentration of, for example, 5×10¹⁷ cm⁻³.

Thereafter, a breakdown voltage holding layer 122 is formed on buffer layer 121 as shown in FIG. 9. As breakdown voltage holding layer 122, a layer made of SiC with n conductivity type is formed by a vapor phase growth method, a liquid phase growth method, or the like. Breakdown voltage holding layer 122 has a thickness of, for example, 15 μm. Further, n-type conductive impurities in breakdown voltage holding layer 122 have a concentration of, for example, 5×10¹⁵ cm⁻³.

Subsequently, ions are implanted into epitaxial layer 120 as shown in FIGS. 7 and 8 (step S5). In the present embodiment, a p-type well region 123, an n⁺ source region 124, and a p⁺ contact region 125 are formed as shown in FIG. 7, as described below. Firstly, well region 123 is formed by selectively implanting impurities with p conductivity type into a portion of breakdown voltage holding layer 122. Thereafter, source region 124 is formed by selectively implanting n-type conductive impurities into a prescribed region, and contact region 125 is formed by selectively implanting conductive impurities with p conductivity type into a prescribed region. Selective implantation of impurities is performed, for example, using a mask made of an oxide film. The mask is removed after each implantation of impurities.

After such an implantation step, activation annealing treatment may be performed. For example, annealing is performed in an argon atmosphere, at a heating temperature of 1700° C., for 30 minutes.

Through these steps, epitaxial wafer 100 including SiC substrate 2 and epitaxial layer 120 formed on SiC substrate 2 as shown in FIG. 7 can be prepared.

Next, a front surface 100a of epitaxial wafer 100 is cleaned. Specifically, oxide film 3 is formed on front surface 100a of epitaxial wafer 100 using O plasma, as shown in FIGS. 8 and 10 (step S2).

Step S2 herein is identical to step S2 of forming oxide film 3 on front surface 1a of SiC substrate 1 in accordance with Embodiment 1. However, if front surface 100a is damaged by implanting ions into the epitaxial wafer in step S5, a damaged layer may be oxidized to be removed. In this case, for example, a portion from front surface 100a toward SiC substrate 2 with a depth of more than 10 nm and not more than 100 nm is oxidized.

Subsequently, oxide film 3 formed on front surface 100a of epitaxial wafer 100 is removed (step S3). Since step S3 herein is identical to step S3 of removing oxide film 3 formed on front surface 1a of SiC substrate 1 in accordance with Embodiment 1, the description thereof will not be repeated.

By performing the above steps (S1 to S5), impurities, particles, and the like adhering to front surface 100a of epitaxial wafer 100 can be cleaned. It is to be noted that, as in Embodiment 1, steps S2 step S3 may be performed repeatedly, and another cleaning step may further be included. Thereby, an epitaxial wafer 101 having a front surface 101a with reduced impurities and particles as shown for example in FIG. 11 can be implemented.

It is to be noted that any of cleaning apparatus 10 shown in FIG. 1 and cleaning apparatus 20 shown in FIG. 6 may be used to clean epitaxial wafer 100 in accordance with the present embodiment. When cleaning apparatus 10 shown in FIG. 1 is used, epitaxial wafer 100 having oxide film 3 formed thereon is transported in connection unit 13 of cleaning apparatus 10. Thus, connection unit 13 has a shape which allows epitaxial wafer 100 or a susceptor having epitaxial wafer 100 placed thereon to be transported.

As described above, according to the cleaning method for epitaxial wafer 100 in accordance with the present embodiment, since SiC is crystallographically robust, oxide film 3 is formed on front surface 100a of epitaxial wafer 100 using O plasma which cannot be employed in Si due to damage. Oxide film 3 can be easily formed by utilizing active O caused by O plasma. Thus, impurities, particles, and the like adhering to front surface 100a can be easily taken in into oxide film 3. By removing oxide film 3, impurities, particles, and the like on front surface 100a of epitaxial wafer 100 can be removed. Further, since the SiC semiconductor is a stable compound, epitaxial wafer 100 is less damaged even if O plasma is used. Therefore, the cleaning method in accordance with the present embodiment can exhibit a cleaning effect on front surface 100a of epitaxial wafer 100.

By performing the cleaning method for epitaxial wafer 100 as the SiC semiconductor in accordance with the present embodiment, epitaxial wafer 101 having front surface 101a with reduced impurities and particles as shown in FIG. 11 can be manufactured. If an insulating film constituting a semiconductor device such as a gate oxide film is formed on front surface 101a to fabricate the semiconductor device, characteristics of the insulating film can be improved, and impurities, particles, and the like existing at an interface between front surface 101a and the insulating film and within the insulating film can be reduced. Therefore, the semiconductor device can have an improved breakdown voltage when a reverse voltage is applied, and can have improved stability and long-time reliability of operation when a forward voltage is applied. Consequently, the cleaning method for the SiC semiconductor in accordance with the present invention is particularly suitably used for front surface 100a of epitaxial wafer 100 before the gate oxide film is formed.

Epitaxial wafer 101 cleaned by the cleaning method in accordance with the present embodiment can be suitably used for a semiconductor device having an insulating film, because the insulating film is formed on cleaned front surface 101a and thus characteristics of the insulating film can be improved. Therefore, epitaxial wafer 101 cleaned in accordance with the present embodiment can be suitably used for, for example, a semiconductor device having an insulated gate type field effect unit such as a Metal Oxide Semiconductor Field Effect Transistor (MOSFET) and an Insulated Gate Bipolar Transistor (IGBT), a Junction Field-Effect Transistor (JFET), and the like.

In Embodiment 1, the method of cleaning front surface 1a of SiC substrate 1 has been described. In Embodiment 2, the method of cleaning front surface 100a of epitaxial wafer 100 including SiC substrate 2 and SiC epitaxial layer 120 formed on SiC substrate 2, SiC epitaxial layer 120 having front surface 100a implanted with ions, has been described. However, the cleaning method in accordance with the present invention is also applicable to a SiC epitaxial layer having a front surface not implanted with ions. Further, in the case of cleaning epitaxial wafer 100, at least one of front surface 2a of SiC substrate 2 constituting epitaxial wafer 100 and front surface 100a of epitaxial wafer 100 may be cleaned. That is, the cleaning method for the SiC semiconductor in accordance with the present invention includes a case (i) of cleaning a SiC substrate, and a case (ii) of cleaning an epitaxial wafer having a SiC substrate and a SiC epitaxial layer formed on the SiC substrate. The SiC epitaxial layer in case (ii) includes the one implanted with ions from a front surface and the one not implanted with ions.

### EXAMPLES

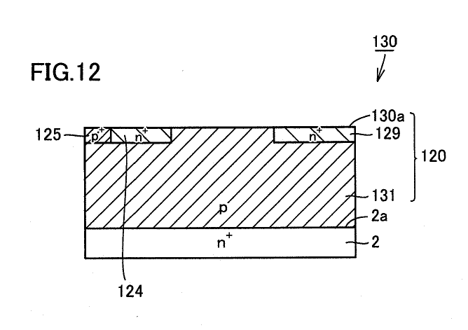

In the present Examples, an effect of forming an oxide film using O plasma was examined by cleaning an epitaxial wafer 130 shown in FIG. 12 as a SiC semiconductor. It is to be noted that FIG. 12 is a cross sectional view schematically showing epitaxial wafer 130 to be cleaned in the Examples.

### The Present Invention's Example 1

Specifically, firstly, a 4H—SiC substrate having front surface 2a was prepared as SiC substrate 2 (step S1).

Next, a p-type SiC layer 131 having a thickness of 10 μm and a concentration of impurities of 1×10¹⁶ cm⁻³ was grown as a layer constituting epitaxial layer 120, by the CVD method (step S4).

Subsequently, using SiO₂ as a mask, source region 124 and a drain region 129 having phosphorus (P) as n-type impurities and a concentration of impurities of 1×10¹⁹ cm⁻³ were formed, and contact region 125 having aluminum (Al) as p-type impurities and a concentration of impurities of 1×10¹⁹ cm⁻³ was also formed (step S5). The mask was removed after each ion implantation.

Next, activation annealing treatment was performed. The activation annealing treatment was performed at a heating temperature of 1700 to 1800° C., for a heating time of 30 minutes, using Ar gas as an atmosphere gas. Thereby, epitaxial wafer 130 having a front surface 130a was prepared.

Subsequently, front surface 130a of epitaxial wafer 130 was cleaned using cleaning apparatus 10 shown in FIG. 1.

Specifically, an oxide film was formed on front surface 130a of prepared epitaxial wafer 130, using O plasma (step S2). In step S2, parallel plate type RIE was used as formation unit 11, epitaxial wafer 130 was placed inside formation unit 11, and then O plasma was generated under conditions described below. An oxide film was formed in a state where O₂ gas was supplied at 50 sccm, a pressure of an atmosphere inside formation unit 11 was set to 1.0 Pa, a back surface of SiC substrate 2 in epitaxial wafer 130 was heated to 400° C., and a power of 500 W was applied. It was confirmed that a 1 nm-thick oxide film was thereby able to be formed on front surface 130a of epitaxial wafer 130.

Next, epitaxial wafer 130 having the oxide film formed thereon in formation unit 11 was transported to removal unit 12. On that occasion, epitaxial wafer 130 was transported through the inside of connection unit 13 having an atmosphere cut off from the air.

Subsequently, the oxide film was removed using HF (step S3). In step S3, oxide film 3 was removed by storing HF within removal unit 12 and immersing epitaxial wafer 130 in HF. It was confirmed that the oxide film formed in step S2 was thereby able to be removed.

Thereafter, epitaxial wafer 130 was taken out of cleaning apparatus 10, and the front surface of epitaxial wafer 130 was cleaned with pure water (i.e., the pure water rinsing step). Subsequently, epitaxial wafer 130 was dried by a spinning method (i.e., the drying step).

Next, step S2 of forming the oxide film using O plasma, step S3 of removing the oxide film, the pure water rinsing step, and the drying step described above were repeated.

Through the above steps (steps S1 to S5), front surface 130a of epitaxial wafer 130 was cleaned. On the front surface cleaned in accordance with the Present Invention's Example 1, impurities and particles were reduced, when compared with front surface 130a before cleaning.

### The Present Invention's Example 2

In the Present Invention's Example 2, firstly, epitaxial wafer 130 shown in FIG. 12 identical to that in the Present Invention's Example 1 was prepared.

Next, epitaxial wafer 130 was cleaned. Although a cleaning method for epitaxial wafer 130 in accordance with the Present Invention's Example 2 was basically identical to the cleaning method for epitaxial wafer 130 in accordance with the Present Invention's Example 1, it was different in that F plasma was used instead of HF in step S3 of removing the oxide film, and in that cleaning apparatus 20 shown in FIG. 6 was used instead of cleaning apparatus 10 shown in FIG. 1.

Specifically, in the Present Invention's Example 2, an oxide film was formed using O plasma, with parallel plate type RIE cleaning apparatus 20 shown in FIG. 6 (step S2). In step S2, epitaxial wafer 130 was placed inside chamber 21 shown in FIG. 6, and then O plasma was generated under conditions identical to those in the Present Invention's Example 1. Specifically, an oxide film was formed in a state where O₂ gas was supplied from the first gas supply unit 22 at 50 sccm, a pressure of an atmosphere inside chamber 21 was set to 1.0 Pa, the back surface of SiC substrate 2 in epitaxial wafer 130 was heated to 400° C., and a power of 500 W was applied. It was confirmed that a 1 nm-thick oxide film was thereby able to be formed on front surface 130a of epitaxial wafer 130.

Subsequently, with epitaxial wafer 130 being placed inside chamber 21, the oxide film was removed using F plasma (step S3). In step S3, the oxide film was removed in a state where supply of O from the first gas supply unit 22 was stopped, F₂ gas was supplied from the second gas supply unit 23 at 30 sccm, the pressure of the atmosphere inside chamber 21 was set to 1.0 Pa, the back surface of SiC substrate 2 in epitaxial wafer 130 was heated to 400° C., and a power of 300 W was applied. It was confirmed that the oxide film formed in step S2 was thereby able to be removed. It was also confirmed that the oxide film formed in step S2 was able to be removed more uniformly (i.e., with reduced in-plane variations) than that in the Present Invention's Example 1.

Through the above steps (steps S1 to S5), front surface 130a of epitaxial wafer 130 was cleaned. On the front surface cleaned in accordance with the Present Invention's Example 2, impurities and particles were reduced, when compared with front surface 130a before cleaning. Further, on the cleaned front surface, the oxide film did not remain locally.

As described above, according to the present Examples, it has been found that a cleaning effect on a SiC semiconductor can be exhibited by forming an oxide film on a front surface of the SiC semiconductor using O plasma, and removing the oxide film.

It has been also found that, by removing the oxide film formed on the front surface of the SiC semiconductor using F plasma, impurities, particles, and the like adhering to the front surface can be removed to reduce in-plane variations, and thus the SiC semiconductor can be cleaned to have good front surface characteristics.

Although the embodiments and examples in accordance with the present invention have been described above, it is originally intended to combine features of the embodiments and examples as appropriate. Further, it should be understood that the embodiments and examples disclosed herein are illustrative and non-restrictive in every respect. The scope of the present invention is defined by the scope of the claims, rather than the embodiments and examples described above, and is intended to include any modifications within the scope and meaning equivalent to the scope of the claims.

### REFERENCE SIGNS LIST

1, 2: SiC substrate, 1a, 2a, 100a, 101a, 130a: front surface, 3: oxide film, 10, 20: cleaning apparatus, 11: formation unit, 12: removal unit, 13: connection unit, 21: chamber, 22: the first gas supply unit, 23: the second gas supply unit, 24: vacuum pump, 100, 101, 130: epitaxial wafer, 120: epitaxial layer, 121: buffer layer, 122: breakdown voltage holding layer, 123: well region, 124: source region, 125: contact region, 129: drain region, 131: p-type SiC layer.

1. A cleaning method for a silicon carbide semiconductor, comprising the steps of:
forming an oxide film having a thickness of not less than one molecular layer and not more than 30 nm on a front surface of a silicon carbide semiconductor; and
removing said oxide film,
wherein oxygen plasma is used in the step of forming said oxide film.

2. A cleaning method for a silicon carbide semiconductor, comprising the steps of:
forming an oxide film on a front surface of a silicon carbide semiconductor; and
removing said oxide film,
wherein, in the step of forming said oxide film, said oxide film is formed at a temperature of not less than 200° C. and not more than 700° C., using oxygen plasma.

3. The cleaning method for a silicon carbide semiconductor according to claim 2, wherein, in the step of forming said oxide film, said oxide film is formed at a pressure of not less than 0.1 Pa and not more than 20 Pa.

4. The cleaning method for a silicon carbide semiconductor according to claim 2, wherein hydrogen fluoride is used in the step of removing said oxide film.

5. A cleaning method for a silicon carbide semiconductor, comprising the steps of:
forming an oxide film on a front surface of a silicon carbide semiconductor; and
removing said oxide film
wherein said silicon carbide semiconductor is transported in an atmosphere cut off from air between the step of forming said oxide film and the step of removing said oxide film.

6. A cleaning apparatus for a silicon carbide semiconductor, comprising:
a formation unit for forming an oxide film on a front surface of a silicon carbide semiconductor using oxygen plasma;
a removal unit for removing said oxide film; and
a connection unit for connecting said formation unit and said removal unit to allow said silicon carbide semiconductor to be transported,
wherein a region for transporting said silicon carbide semiconductor in said connection unit can be cut off from air.

7. A cleaning apparatus for a silicon carbide semiconductor, comprising:
a formation unit for forming an oxide film on a front surface of a silicon carbide semiconductor using oxygen plasma; and
a removal unit for removing said oxide film,
wherein said formation unit and said removal unit are identical.
